(19) United States
(12) Patent Application Publication
(10) Pub. No.: US 2010/0117744 A1
(43) Pub. Date: May 13, 2010

(54) PHASE ERROR CORRECTION IN ROTARY TRAVELING WAVE OSCILLATORS

(75) Inventors: Koji Takinami, Saratoga, CA (US); Richard Walsworth, Mento Park, CA (US)

Correspondence Address: SNELL & WILMER L.L.P. (Panasonic), 600 ANTON BOULEVARD, SUITE 1400, COSTA MESA, CA, 92626, US

(73) Assignee: Matsushita Electric Industrial Co., Ltd.

(21) Appl. No.: 12/268,201

(22) Filed: Nov. 10, 2008

(51) Int. Cl. H03B 27/00; H03K 3/03

(52) U.S. Cl. 331/45; 331/57

(57) ABSTRACT

An RTWO apparatus includes an N-phase RTWO (N is an integer greater than or equal to two) and a phase correction circuit. The N-phase RTWO includes a closed-loop transmission line formed as a Moebius strip. The closed-loop transmission line includes N transmission line segments, to which N voltage controlled capacitors are coupled. The N transmission line segments provide N output phases. The phase correction circuit operates to detect phase errors between output phases, and, depending on the detected phase errors, generates N control voltages for controlling the capacitances of the N voltage controlled capacitors. Controlling the capacitances of the N voltage controlled capacitors in this coordinated manner reduces the phase errors among the N output phases, thereby providing a phase accurate multi-phase RTWO output.

### FIELD OF THE INVENTION

The present invention relates to electronic oscillators. More specifically, the present invention relates to correcting for phase errors in rotary traveling wave oscillators (RTWOs).

### BACKGROUND OF THE INVENTION

An electronic oscillator is a type of electronic circuit that produces a periodic signal. Electronic oscillators are used in a wide variety of applications including digital sampling circuits and quadrature oscillator generators in communications transceivers, for example.

Many modern electronic systems require electronic oscillators capable of generating signals at microwave and millimeter-wave frequencies. Conventional electronic oscillators (e.g., those using lumped element tank circuits) are limited in their ability to generate signals at these frequencies while also maintaining low phase noise. For this reason, alternative oscillator mechanisms have been sought. One category of electronic oscillators that has gained recent interest as a possible alternative is the category of oscillators known as “wave-based” oscillators. Wave-based oscillators dispense with the need for lumped element tank circuits and, instead, rely on the distributed inductance and capacitance of a transmission line to achieve oscillation. Recent developments in wave-based oscillator design have demonstrated the ability of wave-based oscillators to operate at high frequencies, low power, and low phase noise. These characteristics have made wave-based oscillators attractive candidates for microwave and millimeter-wave applications.

FIG. 1 is a drawing of one type of wave-based oscillator, known as a rotary traveling wave oscillator (RTWO) 10, which is described in U.S. Pat. Nos. 6,556,089 and 7,218,180 to Wood. The RTWO 10 comprises a closed-loop differential transmission line 15 and a plurality of regenerative circuits 21. The closed-loop differential transmission line 15 includes a physically and electromagnetically endless signal trace formed in a single plane so that the signal trace has two generally parallel and concentric signal trace loops 15a and 15b that merge at a crossover 19. The signal trace of the transmission line 15 has a length l, which corresponds to two ‘laps’ of the transmission line 15 as defined between the spaced signal loop traces 15a and 15b and through the crossover 19. The crossover 19 produces a Moebius strip effect, whereby the signal traces of the signal trace loops 15a and 15b invert from lap to lap.

The regenerative circuits 21 have input/output terminals connected to the signal trace loops 15a and 15b and are evenly distributed along the closed-loop of the transmission line 15. During start-up, when power is first applied to the regenerative circuits 21, a traveling wave is generated from inherent noise within the regenerative circuits 21. The regenerative circuits 21 reinforce the traveling wave as it is created, forcing it to travel in either a clockwise or counterclockwise direction around the closed-loop differential transmission line 15, the direction of rotation depending on the start-up conditions. Once the traveling wave is fully established, the regenerative circuits 21 continue to reinforce (i.e., amplify) the traveling wave, to counter losses the traveling wave experiences as it travels along the transmission line 15. Typically, the regenerative circuits 21 are implemented as pairs of cross-coupled inverters, like the pair of cross-coupled inverters 23a and 23b in FIG. 2A. When formed with other circuitry in a complementary metal oxide semiconductor (CMOS) process, the pairs of cross-coupled inverters 23a and 23b are implemented as CMOS inverter, like the CMOS inverter 25 shown in FIG. 2B.

FIG. 3 shows idealized component oscillation waveforms Φ1 and Φ2 that appear at the input/output terminals of the regenerative circuits 21. The component oscillation waveforms Φ1 and Φ2 are substantially square and differential, crossing at a midpoint Vdd/2 of the maximum signal amplitude Vdd. The midpoint Vdd/2 can be considered as a ‘null’ point since the instant that both component oscillation waveforms Φ1 and Φ2 are at the same potential, there is no displacement current flow present in nor any differential voltage between the signal trace loops 15a and 15b.

The null point of the component oscillation waveforms Φ1 and Φ2 sweeps around the closed-loop differential transmission line 15 at a rate of 1/(2 Tₚ), where Tₚ is equal to the half period of the component oscillation waveforms Φ1 and Φ2. The sweep rate 1/(2 Tₚ) defines the fundamental oscillating frequency f_{osc} of the RTWO 10, and relates to the physical properties of the RTWO 10 as follows: f_{osc}=1/(2 Tₚ)=vₚ/(2 l), where vₚ=(LₒCₒ)^{-1/2} is the phase velocity of the component oscillation waveforms Φ1 and Φ2 traveling in the transmission line 15, Lₒ and Cₒ are the inductance and capacitance per unit length of the transmission line 15, and l is the length of the transmission line 15.

In addition to having the ability to oscillate at high frequencies and with low phase noise, the RTWO 10 has excellent power dissipation characteristics, even at high frequencies. In fact, once a traveling wave is generated in the RTWO 10, little power is required to sustain it. The energy used to switch the regenerative circuits 21 is part of the wave energy that circulates around the transmission line 15. When the regenerative circuits 21 are formed using CMOS technology, i.e., using CMOS inverters 25 like those in FIG. 2B, energy that goes into charging the MOS capacitors of the inverters' transistors becomes transmission line energy that is recirculated in the closed electromagnetic path. Hence, losses are not dominated by CV² f losses but rather by I²R dissipation in the transmission line signal line trace. These power dissipation characteristics of the RTWO 10 make the RTWO 10 attractive for high-frequency, battery-powered applications, such as wireless handset applications, for example.

Another attractive feature of the RTWO 10 is that it provides a multi-phase output. Various applications require or use multiple signal phases. For example, quadrature modulators and demodulators in communications transceivers require the generation of in-phase and quadrature phase local oscillator signals which are ninety degrees out of phase with respect to each other. Digital sampling circuits also use multi-phase clocks to increase effective sampling rates and data transmission speeds. For example, data transmission speeds can be increased beyond the fundamental switching speed limits of the underlying logic of a digital sampling circuit by serializing data sampled by multiple phases of a multi-phase clock. Conventional multi-phase clock generators employ phased-locked loops and delay-locked loops to generate the multi-phase clock. However those approaches are complex, do not generate square waves, exhibit high levels of jitter, and suffer from large area penalties. The RTWO 10, at least in theory, avoids these problems, naturally generating and providing high-frequency multi-phase square wave signals at different physical positions along the transmission line 15.

FIG. 4 is a drawing of an RTWO 40 highlighting the RTWO's inherent multi-phase capability. The RTWO 40 is substantially the same as the RTWO 10 in FIG. 1, except that it is formed in the shape of a square and omits the regenerative circuits 21, to best illustrate the RTWO's multi-phase capability. The circled plus and minus signs along the differential close-loop transmission line 15 indicate the polarity of the rotating traveling wave (assumed to be traveling in the clock-wise direction, as indicated by the large arrow at the top of the drawing), and the small arrows along the first and second signal trace loops 15a and 15b indicate the direction of current flow. As explained above, the component oscillation waveforms Φ1 and Φ2 at the input/output terminals of any given regenerative circuit 21 arrive back at the input/output terminals of the same regenerative circuit 21 after traversing one lap of the transmission line 15. Coherent oscillation of the RTWO 30 occurs when the signal in the transmission line 15 meets this requirement for all connected regenerative circuits 21.

FIGS. 5A-H show the component oscillation waveforms Φ1 and Φ2 through a full cycle to start of the next cycle for eight different electrical-length spacings of 45° between sample positions along the closed-loop differential transmission line 15. The 0°/360° location (see FIG. 3) is used as an arbitrarily chosen phase reference point. To complete a full cycle phase rotation from 0° to 360°, the component oscillation waveforms Φ1 and Φ2 must traverse two laps (i.e., the full length l of the transmission line 15). FIG. 5A shows the component oscillation waveforms Φ1 and Φ2 at the 0°/360° phase reference position. FIG. 5B shows the component oscillation waveforms Φ1 and Φ2 after having traversed ⅛ of the total length l of the transmission line 15; FIG. 5C shows the component oscillation waveforms Φ1 and Φ2 after a traversal of ¼ of the length l of the transmission line 15 (i.e., one-half of a lap); and so on, as illustrated in the remaining FIGS. 4D-H. It is seen, therefore, that a multi-phase output can be produced by tapping the transmission line 15 at carefully selected and spaced positions.

While the RTWO 40 can be used to implement an oscillator having a multi-phase output, the phase accuracy among the multiple phases is not always as accurate as needed or desired, particularly when the RTWO 40 is configured to operate at microwave and millimeter-wave frequencies. Phase accuracy is adversely influenced by a number of factors, including device mismatches among the regenerative circuits 21 (e.g., caused by processing variations), asymmetry of the physical layout of the RTWO 40, lack of uniformity in signal trace widths and other dimensions of the closed-loop differential transmission line 15, and the difficulty in forming the tap positions along the transmission line 15 with the physical precision necessary to achieve a constant phase separation among phases of the multi-phase output.

The lack of phase accuracy in the RTWO 40 detracts from its use in various applications. For example, in quadrature oscillator applications, sub-degree phase accuracy is often required. At microwave and millimeter wave frequencies, this level of phase accuracy may be difficult or even impossible to achieve with currently available RTWOs, such as those described above. Further, in high-frequency multi-phase clock generator applications, the phase accuracy of the RTWO is often so poor that the skew among output phases is greater than can be tolerated. It would be desirable, therefore, to have an RTWO capable of providing a more phase accurate output than can be realized in currently available RTWOs.

### SUMMARY OF THE INVENTION

Rotary traveling wave oscillator (RTWO) apparatuses and methods are disclosed. An exemplary method for correcting phase inaccuracy among output phases of a multi-phase RTWO includes detecting a phase error between first and second output phases of the RTWO and controlling the phase velocities of a traveling wave traveling in first and second transmission line segments of a closed-loop transmission line to reduce the detected phase error. According to one aspect of the invention, first and second voltage controlled capacitors having substantially the same capacitance versus voltage characteristics are coupled to the first and second transmission line segments, and first and second control voltages for controlling the first and second voltage controlled capacitors are generated based on the detected phase error. Applying the control voltages causes the capacitance of the first transmission line segment to increase by a capacitance differential +ΔC and the capacitance of the second transmission line segment to decrease by a capacitance differential −ΔC. Controlling the voltage controlled capacitors in this manner decreases the phase velocity of a traveling wave in the first transmission line segment compared to the phase velocity of the traveling wave in the second transmission line section. This allows the phase error between the first and second output phase of the RTWO to be reduced while the total capacitance of the closed-loop transmission line remains at a constant level.

The RTWO methods and apparatus of the present invention are extensible to multi-phase RTWOs having more than two phases. An exemplary N-phase RTWO, where N is a positive integer greater than or equal to two, includes a closed-loop transmission line formed as a Moebius strip. The closed-loop transmission line includes N transmission line segments, to which N voltage controlled capacitors are coupled. The N transmission line segments provide N output phases. A phase correction circuit operates to detect phase errors between output phases, and, depending on the detected phase errors, generates N control voltages for controlling the capacitances of the N voltage controlled capacitors. Controlling the capacitances of the N voltage controlled capacitors in this coordinated manner reduces the phase errors among the N output phases, thereby providing a phase accurate multi-phase RTWO output.

Further features and advantages of the present invention, including a description of the structure and operation of the above-summarized and other exemplary embodiments of the invention, are described in detail below with respect to accompanying drawings, in which like reference numbers are used to indicate identical or functionally similar elements.

### BRIEF DESCRIPTION OF THE DRAWINGS

FIG. 1 is a layout view drawing of a typical rotary traveling wave oscillator (RTWO);

FIG. 2A is a circuit diagram of a pair of cross-coupled inverters;

FIG. 2B is a transistor level circuit diagram of a pair of cross-coupled inverters formed from a complementary metal oxide semiconductor (CMOS) process;

FIG. 3 is a timing diagram showing idealized component oscillation waveforms Φ1 and Φ2 that appear at the input/output terminals of the regenerative circuits of the RTWO in FIG. 1;

FIG. 4 is a drawing of a typical RTWO, highlighting the RTWO's inherent multi-phase capability;

FIGS. 5A-H are timing diagrams of the component oscillation waveforms Φ1 and Φ2 through a full cycle to start of the next cycle for eight different sample positions along the closed-loop transmission line of the RTWO in FIG. 4;

FIG. 6 is a drawing of an RTWO apparatus, according to an embodiment of the present invention;

FIG. 7 is a drawing illustrating how the phase velocity of a traveling wave is decreased in a first transmission line segment of a transmission line by increasing the capacitance of the first transmission line segment by a capacitance differential +ΔC and is increased in a second transmission line segment of the transmission line by decreasing the capacitance of second transmission line segment by a capacitance differential −ΔC;

FIG. 8 is a drawing of an alternative RTWO apparatus, according to an embodiment of the present invention;

FIG. 9 is a drawing of a phase correction circuit which may be used to implement the phase correction circuit of the RTWO apparatus in FIG. 6;

FIG. 10 is a drawing of another phase correction circuit which may be used to implement the phase correction circuit of the RTWO apparatus in FIG. 6;

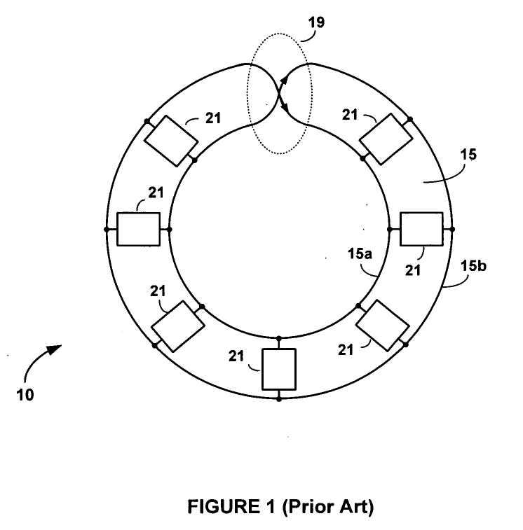

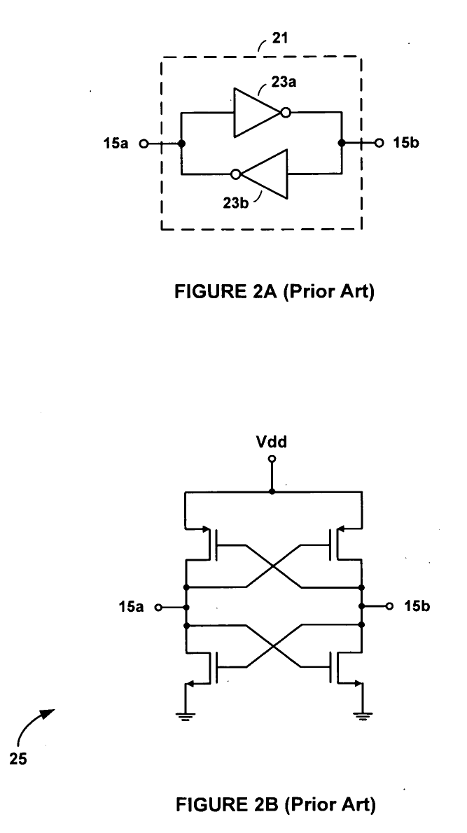

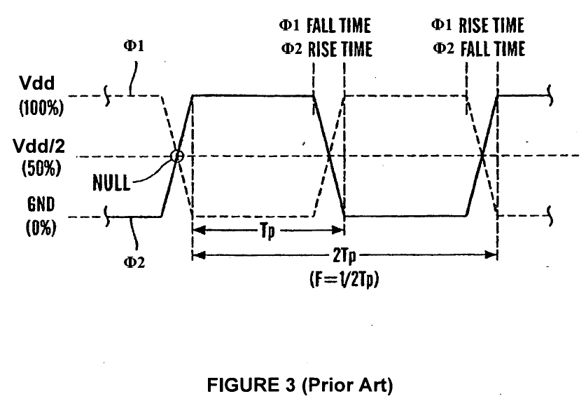

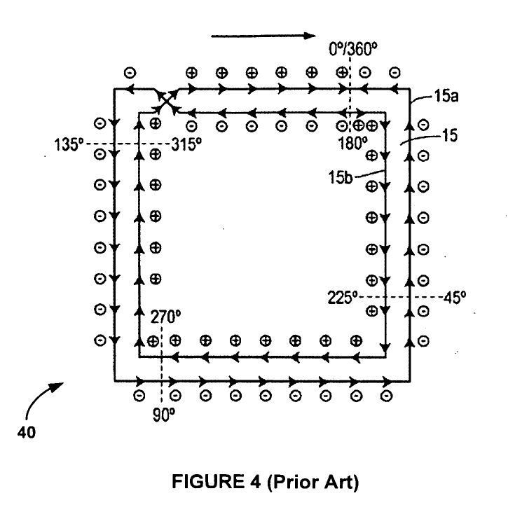

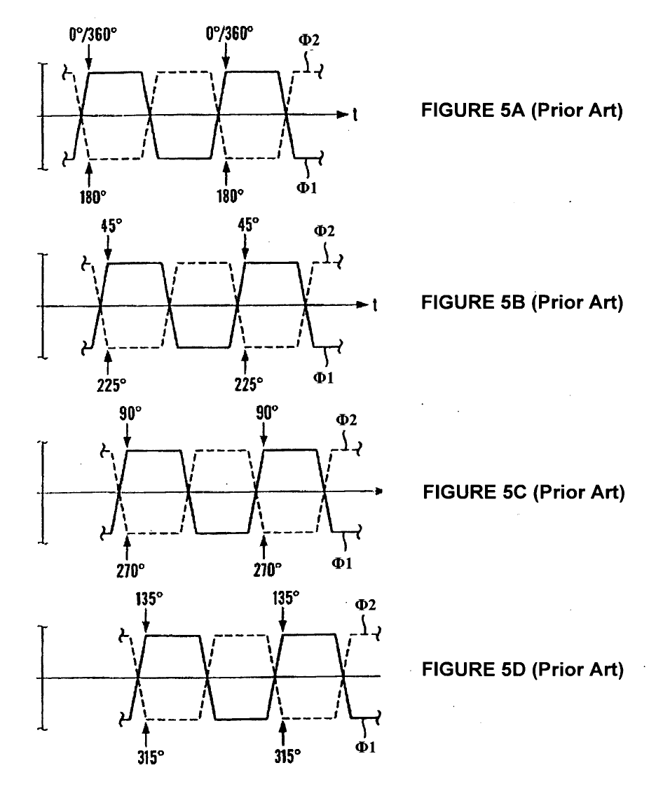

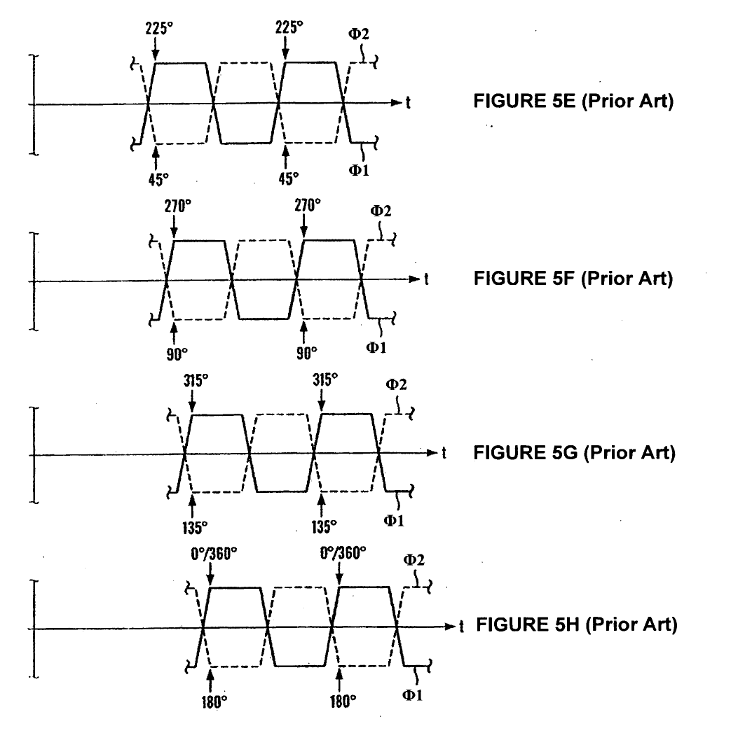

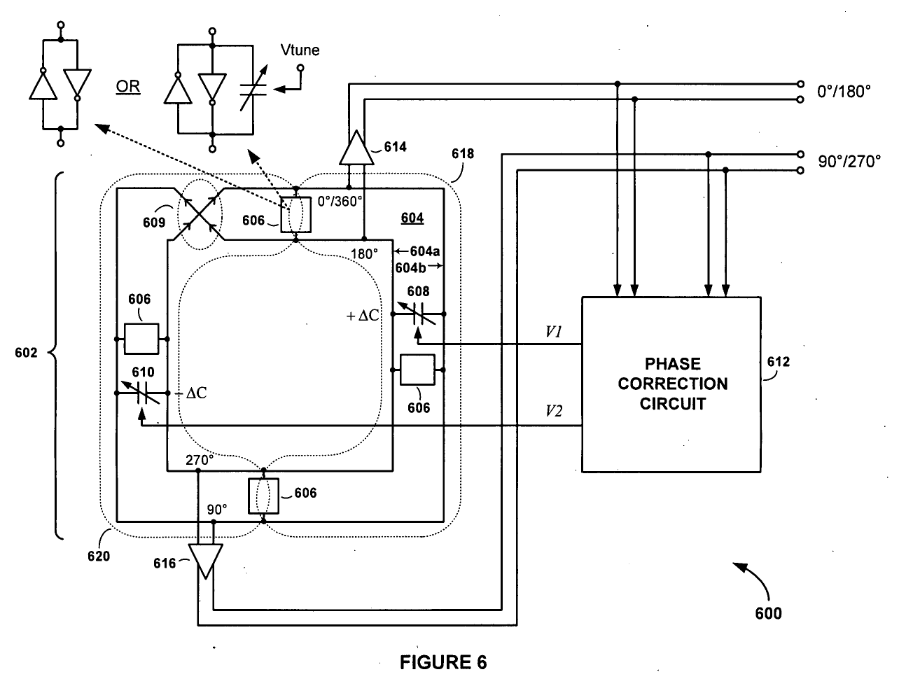

FIG. 1 is a diagram of a factory calibration setup which may be used to perform a factory phase calibration of the RTWO in FIG. 6; and

FIG. 12 is a drawing of a four-phase (N=4) RTWO apparatus, highlighting the fact that the phase error correction methods and apparatus of the present invention are extensible to RTWOs having more than two output phases.

### DETAILED DESCRIPTION

Referring to FIG. 6, there is shown a drawing of a rotary traveling wave traveling oscillator (RTWO) apparatus 600, according to an embodiment of the present invention. The RTWO apparatus 600 comprises an RTWO 602 including a transmission line 604, a plurality of regenerative circuits 606 and first and second voltage controlled capacitors 608 and 610, and a phase correction circuit 612.

The transmission line 604 includes a physically and electromagnetically endless conductive signal trace of length l having generally parallel first and second signal trace loops 604a and 604b that merge at a half-twist 609 so that the signal trace forms a Moebius strip. The first and second signal trace loops 604a and 604b are formed on or within a dielectric or semiconductor substrate, and may be disposed either in a single plane using a planar transformer to complete the half-twist 609, or in separate metal layers with a via to close the loop and connect the first signal trace loop 604a to the second signal trace loop 604b. In one embodiment, the RTWO 602 is formed with other circuitry in an integrated circuit, and manufactured according to a semiconductor manufacturing process, such as the complementary metal oxide semiconductor (CMOS) fabrication process. The RTWO 602 in this exemplary embodiment is formed in the shape of a square. However, it can be formed in other shapes, so long as the length l of the signal trace is of the appropriate length to achieve the desired oscillation frequency.

The regenerative circuits 606 comprise pairs of cross-coupled inverters (or other negative resistance, negative capacitance or nonlinear regenerative means, such as Gunn diodes) having input/output terminals connected to the first and second signal trace loops 604a and 604b. Tuning capacitors may be optionally connected in parallel with the regenerative circuits 606 to provide the ability to frequency tune the RTWO 602, as indicated in FIG. 6. Similar to as in a conventional RTWO, the regenerative circuits 606 operate in a coordinated manner to reinforce (i.e., amplify) a traveling wave as the traveling wave propagates along the transmission line 604, thereby countering I²R losses and allowing the RTWO 602 to sustain oscillation.

The RTWO 602 of the exemplary RTWO apparatus 600 is configured to provide a two-phase differential output, making it suitable for use in a quadrature modulator or demodulator of a communications transceiver, for example. The first phase of the two-phase differential output is provided by a first differential amplifier 614 having a differential input coupled between the first and second signal trace loops 604a and 604b at a first location of the transmission line 604. The second phase is provided by a second differential amplifier 616 having a differential input coupled between the first and second signal trace loops 604a and 604b at a second location of the transmission line 604. The first and second locations are spaced one-half ‘lap’ apart, where a lap corresponds to half the length l of the transmission line 604. Accordingly, the first differential amplifier 614 provides a first differential output signal having a nominal phase of 0°/180° and the second differential amplifier 616 provides a second differential output signal having a nominal phase of 90°/270°.

The first and second voltage controlled capacitors 608 and 610, which may be comprise, for example, first and second varactors, have substantially identical capacitance versus voltage characteristics. They are coupled between the first and second signal trace loops 604a and 604b of the transmission line 604 so that they alternate with the locations at which the first and second differential amplifiers 614 and 616 are coupled to the first and second signal trace loops 604a and 604b. Viewed in another way, the first and second voltage controlled capacitors 608 and 610 are coupled to first and second transmission line segments 618 and 620, respectively of the transmission line 604. As shown in FIG. 6, the first transmission line segment 618 includes the portion of the transmission line 604 that extends from the first location at which the first differential amplifier 614 is coupled to the first and second signal trace loops 604a and 604b to the second location at which the second differential amplifier 616 is coupled to the first and second signal trace loops 604a and 604b. The second transmission line segment 620 has the same length as the first transmission line segment 618 and includes the portion of the transmission line 604 that extends from the second location at which the second differential amplifier 616 is coupled to the first and second signal trace loops 604a and 604b to the first location at which the first differential amplifier 614 is coupled to the first and second signal trace loops 604a and 604b.

The capacitances of the first and second voltage controlled capacitors 608 and 610 are controlled by first and second control voltages V1 and V2, respectively, provided by the phase correction circuit 612. Applying the first and second control voltages V1 and V2 across the first and second voltage controlled capacitors 608 and 610 increases the capacitance of the first transmission line segment 618 by a capacitance differential +ΔC and decreases the capacitance of the second transmission line segment 620 by a capacitance differential −ΔC. As explained in further detail below, the phase correction circuit 612 controls the capacitances of the first and second transmission line segments 618 and 620 in this manner, to correct for phase inaccuracies between the two output phases of the first and second differential amplifiers 614 and 616.

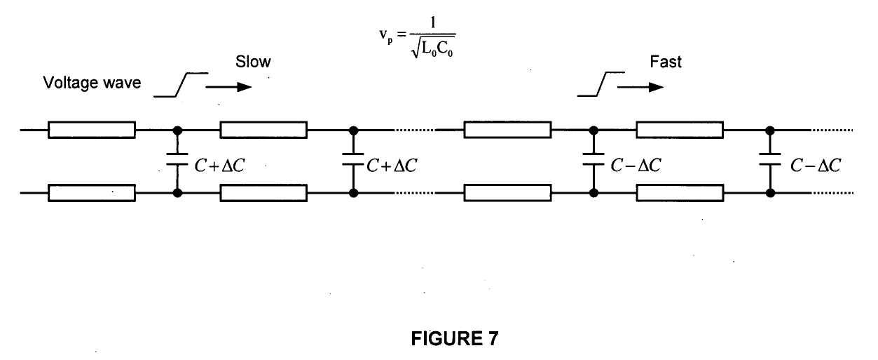

Changing the capacitances of the first and second voltage controlled capacitors 608 and 610 alters the phase velocities of the traveling wave in the first and second transmission line segments 618 and 620 of the RTWO 602. The phase velocity describes the rate at which the phase of a traveling wave propagates along a transmission line (i.e., the propagation speed of the traveling wave), and is defined by vₚ=(LₒCₒ)^{-1/2}, where Lₒ and Cₒ are the inductance and capacitance per unit length of the transmission line. Accordingly, as illustrated in FIG. 7, increasing the capacitance of the first transmission line segment 618 by the capacitance differential +ΔC and decreasing the capacitance of the second transmission line segment 620 by the capacitance differential −ΔC causes the traveling wave in the RTWO 602 to propagate more slowly in the first transmission line segment 618 compared to the rate at which it propagates in the second transmission line segment 620.

The ability to control the propagation speeds of the traveling wave in the first and second transmission line segments 618 and 620 provides the ability to correct for any phase error Δφ that may be present between the output phases of the first and second differential amplifiers 614 and 616. Ideally, the phase error Δφ is zero. However, as was explained above, various factors, such as device mismatches among the regenerative circuits 606 and other electrical components, and asymmetry of the physical layout of the transmission line 604 of the RTWO 602, can cause the phase error to be nonzero. The phase correction circuit 612, which is connected in a feedback arrangement with the RTWO 602, operates to counter these negative influences and force the phase error Δφ to zero. Specifically, the phase correction circuit 612 determines the phase error Δφ between the first and second differential output signals of the first and second differential amplifiers 614 and 616 (i.e., the phase error between the two output phases of the RTWO 602), and, in response, generates the first and control voltages V1 and V2 that set the +ΔC and −ΔC capacitance differentials of the first and second voltage controlled capacitors 608 and 610. The capacitance differential +ΔC of the first transmission line segment 618 and the capacitance differential −ΔC of the second transmission line segment 620 alter the phase velocities of the first and second transmission line segments 618 and 620. Consequently, the phase separation between the two output phases of the first and second differential amplifiers 614 and 616 is also altered.

With the first and second control voltages applied V1 and V2 to the first and second voltage controlled capacitors 608 and 610, the phase correction circuit 612 determines a new phase error between the two output phases of the RTWO 602, and based on the new phase error generates new first and second control voltages V1 and V2 that produce new capacitance differentials +ΔC and −ΔC in the first and second transmission line segments 618 and 620. The RTWO 602 and phase correction circuit 612 operate in this coordinated feedback manner, forcing the phase error Δφ between the two output phases of the RTWO 602 to zero.

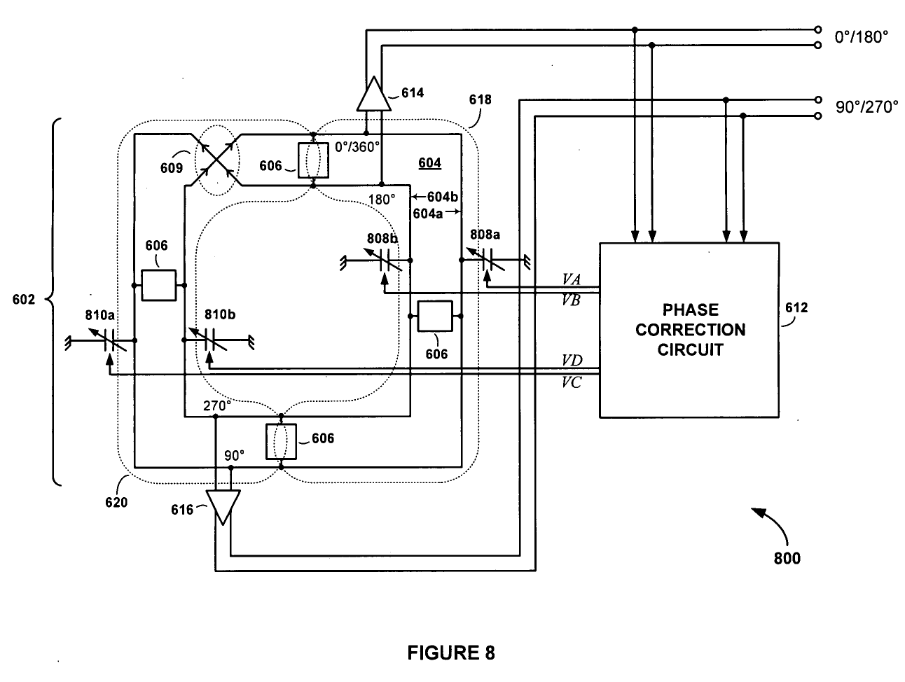

In the RTWO apparatus 600 shown and described above, the first and second first and second voltage controlled capacitors 608 and 610 coupled between the first and second signal trace loops 604a and 604b are used to correct for phase inaccuracies between the two output phases of the first and second differential amplifiers 614 and 616. In an alternative embodiment, shown in FIG. 8, first and second single-ended voltage controlled capacitors 808a and 808b and third and fourth single-ended voltage controlled capacitors 810a and 810b are used, instead. Each of the first, second, third and fourth single-ended voltage controlled capacitors 808a, 808b, 810a and 810b is independently controlled by first, second, third and fourth control voltages VA, VB, VC and VD, respectively, from the phase correction circuit 612 to correct for phase inaccuracies between the two output phases of the first and second differential amplifiers 614 and 616. Single-ended voltage controlled capacitors may also be used in the other embodiments of the invention described below.

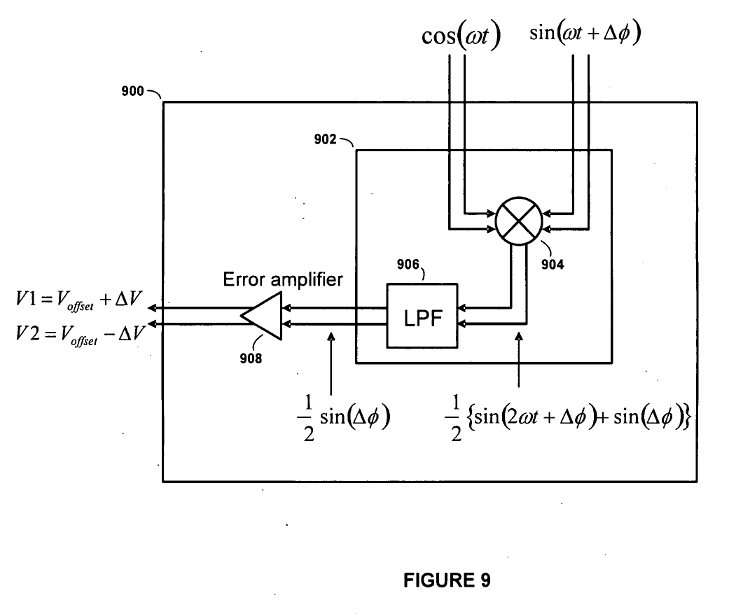

The phase correction circuit 612 of the two-phase RTWO apparatus 600 in FIG. 6 may be implemented in a variety of different ways. FIG. 9 is a drawing of one exemplary phase correction circuit 900 that may be used. The phase correction circuit 900 comprises a phase detector 902, which includes a mixer 904 and a low pass filter (LPF) 906, and a differential error amplifier 908.

When the phase correction circuit 900 in FIG. 9 is used to implement the phase correction circuit 612 of the RTWO apparatus 600 in FIG. 6, the mixer 904 is configured to receive the first and second differential output signals cos(ωt) and sin(ωt+Δφ), where the first differential output signal cos(ωt) is used as a phase reference and the phase error Δφ between the two signals is included in the second differential output signal sin(ωt+Δφ). The mixer 904 operates to combine the first and second differential output signals cos(ωt) and sin(ωt+Δφ), producing a high-frequency component (½)*sin(2ωt+Δφ) and a low-frequency component (½)*sin(Δφ). The LPF 906 filters out the high-frequency component (½)*sin(2ωt+Δφ), leaving the low-frequency component (½)*sin(Δφ) at its output. Finally, based on the phase error Δφ represented in the low-frequency component (½)*sin(Δφ), the differential error amplifier 908 generates the first and second control voltages V1=V_{offset}+ΔV and V2=V_{offset}−ΔV.

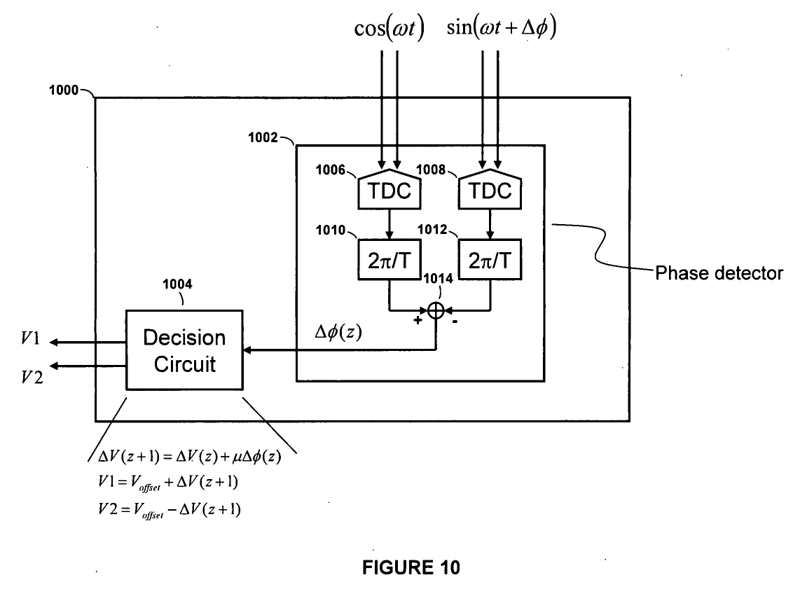

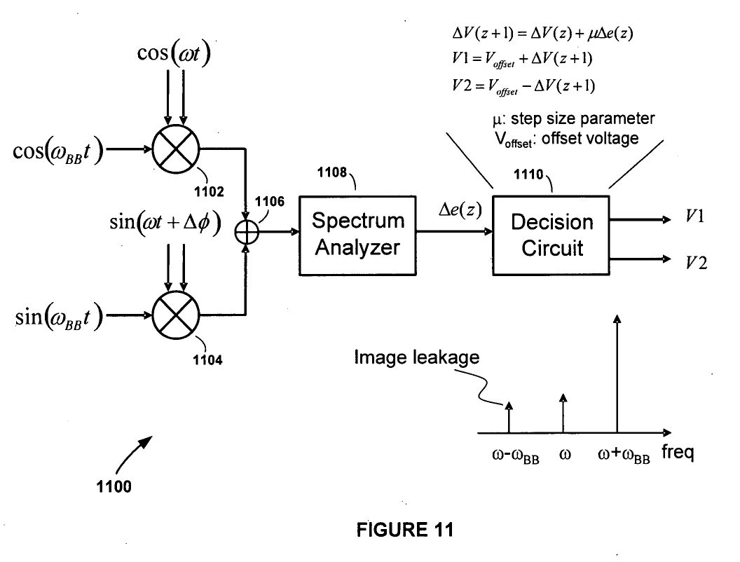

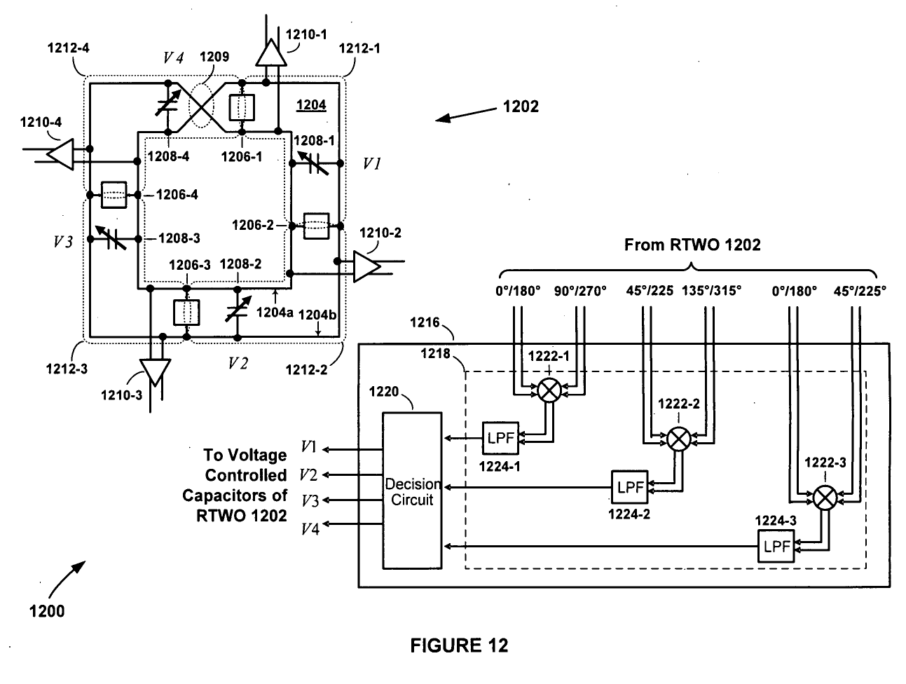

FIG. 10 is a drawing of an alternative phase correction circuit 1000 that may be used to implement the phase correction circuit 612 of the RTWO apparatus 600 in FIG. 6. This phase correction circuit 1000 provides a digital implementation. The phase correction circuit 1000 comprises a digital phase detector 1002 and a decision circuit 1004. The digital phase detector 1002 includes first and second time-to-digital converters (TDCs) 1006 and 1008, first and second time-to-phase converters 1010 and 1012, and a subtractor 1014. The first and second TDCs 1006 and 1008 are configured to sample the first and second differential output signals cos(ωt) and sin(ωt+Δφ), to provide first and second digital time signals. The first and second TDCs 1006 and 1008 can be implemented in variety of ways. One example of a TDC which may be adapted to implement the first and second TDCs 1006 and 1008 of the digital phase detector 1002 here is described in U.S. Pat. No. 7,205,924, which is hereby incorporated by reference.

The first and second time-to-phase converters 1010 and 1012 operate to convert the first and second digital time signals at the outputs of the first and second TDCs 1006 and 1008 to first and second digital phase signals representing the phases of the first and second differential output signals cos(ωt) and sin(ωt+Δφ). The subtractor 1014 forms the difference between the first and second digital phase signals, to produce a digital phase error signal Δφ (z), where z=1, 2, 3, . . . is the sample index.

The digital phase error signal Δφ (z) provides a digital representation of the phase error Δφ detected between the first and second differential output signals cos(ωt) and sin(ωt+Δφ). The decision circuit 1004 operates to add a voltage representation of the digital phase error signal, i.e. μΔφ (z), where μ is a step size parameter (e.g., have a value between 0 and 1), to a voltage differential ΔV(z) used to generate the first and second control voltages V1 and V2 in a previous sample, to generate a new voltage differential ΔV(z+1) having a magnitude dependent upon the phase error Δφ represented in the digital phase error signal Δφ (z). New values for the first and second control voltages V1 and V2 are then computed, i.e., V1=V_{offset}+ΔV(z+1) and V2=V_{offset}−ΔV(z+1).

In the phase correction circuits 900 and 1000 described in FIGS. 9 and 10 above, the process used to generate the first and second control voltages V1 and V2 is performed in the field, e.g., as part of a pre-operation system setup process or during real-time operation. In an alternative embodiment, a factory calibration process is performed to determine values of the first and second control voltages V1 and V2. Later, when the RTWO 602 is configured for real-time operation in the field, the first and second control voltages V1 and V2 determined during the factory calibration process are applied to the first and second voltage controlled capacitors 608 and 610.

FIG. 11 is a drawing of an exemplary factory calibration setup 1100 that may be used to perform the factory calibration process. The factory calibration setup 1100 comprises a local quadrature modulator, which includes a first mixer 1102, second mixer 1104 and summer 1106, a spectrum analyzer 1108, and a decision circuit 1110. The first and second mixers 1102 and 1104 each includes a first and a second differential input. During the calibration process, the first mixer 1102 is configured so that its first differential input receives the first differential output signal cos(ωt) from the first differential amplifier 614, and so that its second differential input receives an in-phase baseband reference signal cos(ω_{BB}t). The second mixer 1104 is configured so that its first differential input receives the second differential output signal sin(ωt+Δφ) from the output of the second differential amplifier 616, and so that its second differential input receives a quadrature phase baseband reference signal sin(ω_{BB}t). The output signal of the first and second mixers 1102 and 1104 are summed by the summer 1106 and coupled to the input of the spectrum analyzer 1108. When the phase error Δφ between the first and second differential output signals cos(ωt) and sin(ωt+Δφ) is at its ideal value of zero, the frequency spectrum of the summed output of the quadrature modulator has no image leakage component at frequency (ω−ω_{BB}). However, when Δφ≠0, an image is present and the spectrum analyzer 1108 generates a digital phase error signal Δe(z) representative of the phase error Δφ. Finally, the decision circuit 1110 generates the first and second control voltages V1 and V2 based on the digital phase error signal Δe(z), similar to the decision circuit 1104 of the phase correction circuit 1004 in FIG. 10.

The phase error correction methods and apparatus described above have been described in the context of a two-phase (N=2) RTWO 602. However, the methods and apparatus are extensible to RTWOs having any number of phases. FIG. 12 shows, for example, a four-phase (N=4) RTWO apparatus 1200 comprising a four-phase RTWO 1202 and a phase correction circuit 1216. The four-phase RTWO 1202 comprises a transmission line 1204, first, second, third and fourth regenerative circuits 1206-1, 1206-2, 1206-3 and 1206-4, and first, second, third and fourth voltage controlled capacitors 1208-1, 1208-2, 1208-3 and 1208-4.

Similar to the transmission line 604 of the RTWO 602 in FIG. 6, the transmission line 1204 of the four-phase RTWO 1202 includes a physically and electromagnetically endless conductive signal trace of length l having generally parallel signal trace loops 1204a and 1204b with a half-twist 1209 so that the signal trace is formed as a Moebius strip.

The first, second, third and fourth regenerative circuits 1206-1, 1206-2, 1206-3 and 1206-4 comprise pairs of cross-coupled inverters (or other suitable regenerative means) having input/output terminals connected to the first and second signal trace loops 1204a and 1204b. Although not shown in FIG. 12, tuning capacitors may be optionally connected in parallel with each of the first, second, third and fourth regenerative circuits 1206-1, 1206-2, 1206-3 and 1206-4 to provide the ability to frequency tune the four-phase RTWO 1202.

The four phases of the four-phase RTWO 1202 are provided by four differential amplifiers 1210-1, 1210-2, 1210-3 and 1210-4, each coupled between the first and second signal trace loops 1204a and 1204b at four different locations of the transmission line 1204. The four differential amplifiers 1210 provide differential outputs having nominal phases of 0°/180°, 45°/225°, 90°/270° and 135°/315°.

The first, second, third and fourth voltage controlled capacitors 1208-1, 1208-2, 1208-3 and 1208-4 have capacitances that are controlled by first, second, third and fourth control voltages V1, V2, V3 and V4 provided by the phase correction circuit 1216, as is explained in more detail below, and are coupled between the first and second signal trace loops 1204a and 1204b so that they alternate with the locations at which the four differential amplifiers 1210-1, 1210-2, 1210-3 and 1210-4 are coupled to the first and second signal trace loops 1204a and 1204b. Viewed in another way, the first, second, third and fourth voltage controlled capacitors 1208-1, 1208-2, 1208-3 and 1208-4 are coupled to first, second, third and fourth transmission line segments 1212-1, 1212-2, 1212-3 and 1212-4 of the transmission line 1204.

The phase correction circuit 1216 is configured in a feedback arrangement between the differential outputs of the first, second, third and fourth differential amplifiers 1210-1, 1210-2, 1210-3 and 1210-4 and the voltage control inputs of the first, second, third and fourth voltage controlled capacitors 1208-1, 1208-2, 1208-3 and 1208-4. As shown in FIG. 12, the phase correction circuit 1216 comprises a phase detection circuit 1218 and a decision circuit 1220. The phase detection circuit 1218 includes first, second and third mixers 1222-1, 1222-2 and 1222-3 and corresponding first, second and third LPFs 1224-1, 1224-2 and 1224-3. The first, second and third mixers 1222-1, 1222-2 and 1222-3 operate to mix the differential output signals of the first and third differential amplifiers 1210-1, 1210-3, the second and fourth differential amplifiers 1210-2, 1210-4, and the first and second differential amplifiers 1210-1, 1210-2, respectively. This allows the phase errors between every two phases of the four phases to be determined.

The first, second and third LPFs 1224-1, 1224-2 and 1224-3 operate to filter out the high-frequency components at the outputs of the first, second and third mixers 1222-1, 1222-2 and 1222-3, thereby leaving first, second and third low-frequency component signals (½)*sin(Δφ_{1,3}), (½)*sin(Δφ_{2,4}) and (½)*sin(Δφ_{1,2}), which include a first phase error Δφ_{1,3} between the differential outputs of the first and third differential amplifiers 1210-1 and 1210-3, a second phase error Δφ_{2,4} between the differential outputs of the second and fourth differential amplifiers 1210-2 and 1210-4, and a third phase error Δφ_{1,2} between the differential outputs of the first and second differential amplifiers 1210-1 and 1210-2. The decision circuit 1220, generates the first, second, third and fourth control voltages V1, V2, V3 and V4 based on the detected first, second and third phase errors Δφ_{1,3}, Δφ_{2,4} and Δφ_{1,2}. In one embodiment, the decision circuit 1220 is configured to perform this control voltage generation process using a least mean squares algorithm. However, any other suitable algorithm may be used. Finally, the first, second, third and fourth control voltages V1, V2, V3 and V4 are used to alter the capacitances of the first, second, third and fourth transmission line segments 1212-1, 1212-2, 1212-3 and 1212-4, to affect the relative phase velocities of the traveling wave propagating in the first, second, third and fourth transmission line segments 1212-1, 1212-2, 1212-3 and 1212-4 so that the first, second and third phase errors Δφ_{1,3}, Δφ_{2,4} and Δφ_{1,2} are reduced. The reduced phase errors are then again detected by the phase detection circuit 1218, and based on the reduced phase error values the decision circuit 1220 generates new first, second, third and fourth control voltages V1, V2, V3 and V4 to further reduce the first, second and third phase errors Δφ_{1,3}, Δφ_{2,4} and Δφ_{1,2}. The RTWO 1202 and phase correction circuit 1216 operate in this coordinated feedback manner, forcing the first, second and third phase errors Δφ_{1,3}, Δφ_{2,4} and Δφ_{1,2} to zero.

Although the present invention has been described with reference to specific embodiments, those embodiments are merely illustrative and not restrictive of the present invention. Further, various modifications or changes to the specifically disclosed exemplary embodiments will be suggested to persons skilled in the art and are to be included within the spirit and purview of this application and scope of the appended claims.

What is claimed is:

1. A rotary traveling wave oscillator (RTWO) apparatus, comprising:
an RTWO; and
a phase correction circuit coupled to said RTWO.

2. The RTWO apparatus of claim 1 wherein said RTWO comprises an N-phase RTWO including a closed-loop transmission line having N transmission line segments, and said phase correction circuit is configured to control phase velocities of a traveling wave that propagates in the N transmission line segments, where N is an integer greater than or equal to two.

3. The RTWO apparatus of claim 2 wherein said RTWO further includes N voltage controlled capacitors coupled to the N transmission line segments.

4. The RTWO apparatus of claim 3 wherein said RTWO includes N outputs providing N output phases and said phase detection circuit is configured between the N outputs and the voltage control inputs of said N voltage controlled capacitors.

5. The RTWO apparatus of claim 4 wherein said phase correction circuit is configured to determine phase errors between output phases of the N output phases and generate N control voltages for controlling the capacitances of said N voltage controlled capacitors.

6. The RTWO apparatus of claim 5 wherein said phase correction circuit controls the N control voltages so that a total capacitance of the closed-loop transmission line remains substantially constant and unchanged.

7. A rotary traveling wave oscillator (RTWO) apparatus, comprising:
a transmission including a physically and electromagnetically endless conductive signal trace having generally parallel first and second signal trace loops connected to one another by a half-twist;
a first voltage controlled capacitor having terminals coupled between the first and second signal trace loops at a first location;
a second voltage controlled capacitor having terminals coupled between the first and second signal trace loops at a second location.

8. The RTWO apparatus of claim 7, further comprising:
a first RTWO output providing a first output phase;
a second RTWO output providing a second output phase; and
a phase correction circuit coupled between said first and second RTWO outputs and the control terminals of said first and second voltage controlled capacitors.

9. The RTWO apparatus of claim 8 wherein said phase correction circuit is configured to control the capacitances of said first and second voltage controlled capacitors to reduce a phase error between the first and second output phases of said first and second RTWO outputs.

10. The RTWO apparatus of claim 8 wherein said phase correction circuit comprises:
a phase detector configured to detect a phase error between the first and second output phases; and
a decision circuit coupled to said phase detector operable to generate first and second control voltages for said first and second voltage controlled capacitors.

11. The RTWO apparatus of claim 10 wherein the first control voltage is generated so that the capacitance of the first voltage controlled capacitor is increased by a capacitance differential +ΔC and the second control voltage is generated so that the capacitance of the second voltage controlled capacitor is decreased by a capacitance differential −ΔC.

12. The RTWO apparatus of claim 8 wherein said RTWO includes one or more regenerative circuits coupled between the first and second signal trace loops.

13. The RTWO apparatus of claim 12 wherein one or more of said one or more regenerative circuits includes one or more tuning capacitors.

14. A method of correcting phase inaccuracy of a rotary traveling wave oscillator (RTWO), comprising:
detecting a phase error between first and second output phases of an RTWO; and
controlling electrical characteristics of first and second transmission line segments of the RTWO to reduce the phase error.

15. The method of claim 14 wherein controlling the electrical characteristics of first and second transmission line segments comprises varying capacitances of the first and second transmission line segments.

16. The method of claim 15 wherein varying the capacitances of the first and second transmission line segments comprises generating first and second control voltages depending on the detected phase error and applying the first and second control voltages to first and second voltage controlled capacitors coupled to the first and second transmission line segments.

17. The method of claim 15 wherein varying the capacitances of the first and second transmission line segments is performed so that the capacitance of the first transmission line segment is increased by a capacitance differential +ΔC and the capacitance of the second transmission line segment is decreased by a capacitance differential −ΔC.

18. The method of claim 14 wherein controlling the electrical characteristics of the first and second transmission line segments comprises increasing a phase velocity of a traveling wave propagating along the first transmission line segment relative to a phase velocity of the traveling wave propagating along the second transmission line segment.

19. The method of claim 14 wherein detecting the phase error between the first and second output phases of the RTWO is performed by a phase correction circuit coupled to said RTWO.

20. The method of claim 14 wherein detecting the phase error between the first and second output phases of the RTWO is performed in a factory calibration process.
